(19) United States
(12) Patent Application Publication
(10) Pub. No.: US 2024/0147776 A1
(43) Pub. Date: May 2, 2024

(54) DISPLAY DEVICE

(71) Applicant: Japan Display Inc., Tokyo (JP)

(72) Inventor: Jun HANARI, Tokyo (JP)

(73) Assignee: Japan Display Inc., Tokyo (JP)

(21) Appl. No.: 18/494,781

(22) Filed: Oct. 26, 2023

(30) Foreign Application Priority Data
Oct. 26, 2022 (JP) 2022-171283

(51) Int. Cl. H10K 59/122; G06F 3/041; H10K 59/40; H10K 59/80

(52) U.S. Cl. CPC H10K 59/122; G06F 3/0412; H10K 59/40; H10K 59/873

(57) ABSTRACT

According to one embodiment, a display device includes a plurality of display elements each including a lower electrode, an upper electrode, and an organic layer between the lower electrode and the upper electrode, a partition which includes a conductive lower portion and an upper portion protruding from a side surface of the lower portion and surrounds each of the display elements, and a touch panel electrode which detects an object contacting or approaching a display area including the display elements. The touch panel electrode includes a first metal line located above the partition and extending along the partition.

### CROSS-REFERENCE TO RELATED APPLICATIONS

This application is based upon and claims the benefit of priority from Japanese Patent Application No. 2022-171283, filed Oct. 26, 2022, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

Display devices may comprise the function of a touch panel which detects the operation of a user relative to a display area. When an electrode for realizing such a function is provided in the display area, the structure of the display device needs to be designed such that the reduction in the display quality by the electrode can be prevented.

### BRIEF DESCRIPTION OF THE DRAWINGS

FIG. 1 is a diagram showing a configuration example of a display device according to a first embodiment.

FIG. 2 is a diagram showing an example of the layout of subpixels.

FIG. 3 is a schematic cross-sectional view of the display device along the III-III line of FIG. 2.

FIG. 4 is a schematic cross-sectional view in which a partition and its vicinity are enlarged.

FIG. 5 is a schematic diagram for explaining the sizes of a rib, the partition, a display element and a first metal line.

FIG. 6 is a schematic plan view of the display device according to the first embodiment.

FIG. 7 is a schematic plan view showing elements provided in a surrounding area.

FIG. 8 is a schematic plan view showing elements for realizing functions related to a touch panel.

FIG. 9 is an enlarged view of the area surrounded by the chained frame IX of FIG. 6.

FIG. 10 is a schematic cross-sectional view of the display device along the X-X line of FIG. 9.

FIG. 11 is a schematic cross-sectional view of the vicinity of an end portion of a conductive layer.

FIG. 12 is a schematic plan view of the area surrounded by the chained frame XII of FIG. 8.

FIG. 13 is a schematic plan view showing another example of a configuration which could be applied to touch panel electrodes and relay lines.

FIG. 14 is a schematic plan view of the area surrounded by the chained frame XIV of FIG. 8.

FIG. 15 is a schematic plan view of leads, a connection portion and a terminal portion.

FIG. 16 is a schematic cross-sectional view of the surrounding area including a first pad.

FIG. 17 is a schematic cross-sectional view of the surrounding area including a second pad.

FIG. 18 is a schematic plan view of pixels and the first metal line according to a first modified example.

FIG. 19 is a schematic plan view of pixels and the first metal line according to a second modified example.

FIG. 20 is a schematic plan view of pixels and the first metal line according to a third modified example.

FIG. 21 is a schematic plan view of pixels and the first metal line according to a fourth modified example.

FIG. 22 is a schematic plan view of pixels and the first metal line according to a fifth modified example.

FIG. 23 is a schematic plan view of pixels and the first metal line according to a sixth modified example.

FIG. 24 is a schematic plan view of pixels and the first metal line according to a seventh modified example.

FIG. 25 is a schematic plan view of pixels and the first metal line according to an eighth modified example.

FIG. 26 is a schematic cross-sectional view of the surrounding area of a display device according to a second embodiment.

FIG. 27 is another schematic cross-sectional view of the surrounding area of the display device according to the second embodiment.

FIG. 28 is a schematic cross-sectional view of the surrounding area of a display device according to a third embodiment.

FIG. 29 is another schematic cross-sectional view of the surrounding area of the display device according to the third embodiment.

FIG. 30 is a schematic cross-sectional view of the display area of a display device according to a fourth embodiment.

### DETAILED DESCRIPTION

In general, according to one embodiment, a display device comprises a plurality of display elements each including a lower electrode, an upper electrode which faces the lower electrode, and an organic layer which is provided between the lower electrode and the upper electrode and emits light based on a potential difference between the lower electrode and the upper electrode, a partition which includes a conductive lower portion and an upper portion protruding from a side surface of the lower portion and surrounds each of the display elements, and a touch panel electrode which detects an object contacting or approaching a display area including the display elements. The touch panel electrode includes a first metal line located above the partition and extending along the partition.

By this configuration, the display quality of a display device comprising the function of a touch panel can be improved.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. The third direction Z is a normal direction relative to a plane including the first direction X and the second direction Y. When various elements are viewed parallel to the third direction Z, the appearance is defined as a plan view.

When the position of an element located in the positive direction of the Z-axis relative to another element is referred to, the term “on” or “above” may be used. When the position of an element located in the opposite direction is referred to, the term “under” or “below” may be used. When the positional relationship between two elements is defined using the terms “on”, “above”, “under”, “below”, “face”, etc., the two elements may be directly in contact with each other, or may be spaced apart from each other as a gap or another element is interposed between them.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

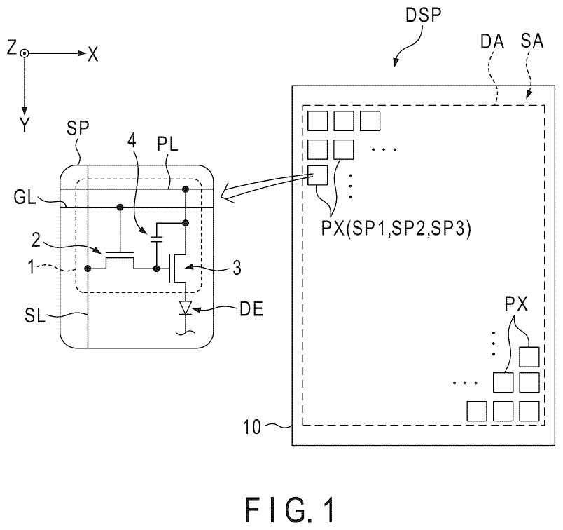

FIG. 1 is a diagram showing a configuration example of a display device DSP according to a first embodiment. The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a red subpixel SP1, a green subpixel SP2 and a blue subpixel SP3. Each pixel PX may include a subpixel SP which exhibits another color such as white in addition to subpixels SP1, SP2 and SP3 or instead of one of subpixels SP1, SP2 and SP3. Each pixel PX may consist of two subpixels SP or four or more subpixels SP.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

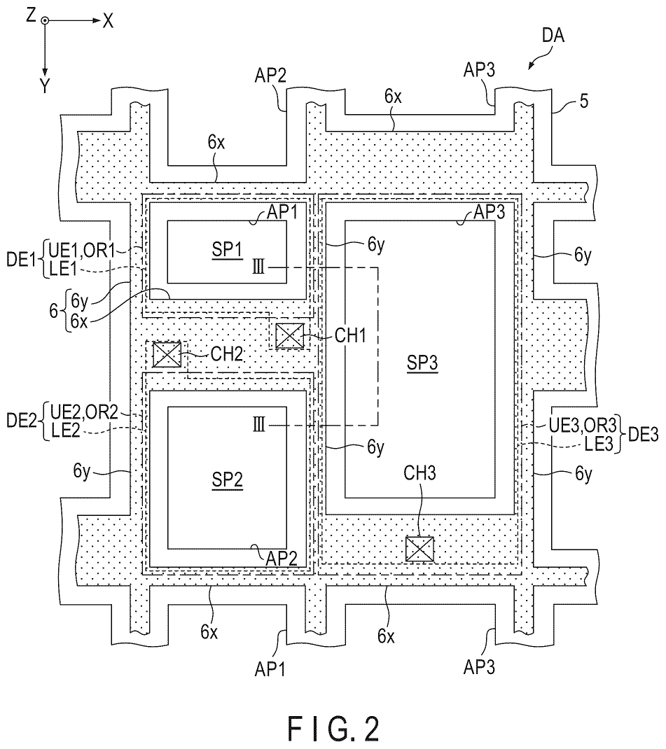

FIG. 2 is a diagram showing an example of the layout of subpixels SP1, SP2 and SP3. In the example of FIG. 2, subpixels SP1 and SP2 are arranged in the second direction Y. Further, each of subpixels SP1 and SP2 is adjacent to subpixel SP3 in the first direction X.

When subpixels SP1, SP2 and SP3 are provided in line with this layout, in the display area DA, a column in which subpixels SP1 and SP2 are alternately provided in the second direction Y and a column in which a plurality of subpixels SP3 are repeatedly provided in the second direction Y are formed. These columns are alternately arranged in the first direction X. It should be noted that the layout of subpixels SP1, SP2 and SP3 is not limited to the example of FIG. 2.

A rib 5 and a partition 6 are provided in the display area DA. The rib 5 comprises pixel apertures AP1, AP2 and AP3 in subpixels SP1, SP2 and SP3, respectively. In the example of FIG. 2, the pixel aperture AP2 is larger than the pixel aperture AP1. The pixel aperture AP3 is larger than the pixel aperture AP2.

The partition 6 is provided in the boundary between adjacent subpixels SP and overlaps the rib 5 as seen in plan view. The partition 6 comprises a plurality of first partitions 6x extending in the first direction X and a plurality of second partitions 6y extending in the second direction Y. The first partitions 6x are provided between the pixel apertures AP1 and AP2 which are adjacent to each other in the second direction Y and between two pixel apertures AP3 which are adjacent to each other in the second direction Y. Each second partition 6y is provided between the pixel apertures AP1 and AP3 which are adjacent to each other in the first direction X and between the pixel apertures AP2 and AP3 which are adjacent to each other in the first direction X.

In the example of FIG. 2, the first partitions 6x and the second partitions 6y are connected to each other. In this configuration, the partition 6 has a grating shape surrounding the pixel apertures AP1, AP2 and AP3 as a whole. In other words, the partition 6 comprises apertures in subpixels SP1, SP2 and SP3 in a manner similar to that of the rib 5.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 and the partition 6 surround each of these display elements DE1, DE2 and DE3.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the contact holes CH1 and CH2 entirely overlap the first partition 6X between the pixel apertures AP1 and AP2 which are adjacent to each other in the second direction Y. The contact hole CH3 entirely overlaps the first partition 6x between two pixel apertures AP3 which are adjacent to each other in the second direction Y. As another example, at least part of the contact hole CH1, CH2 or CH3 may not overlap the first partition 6x.

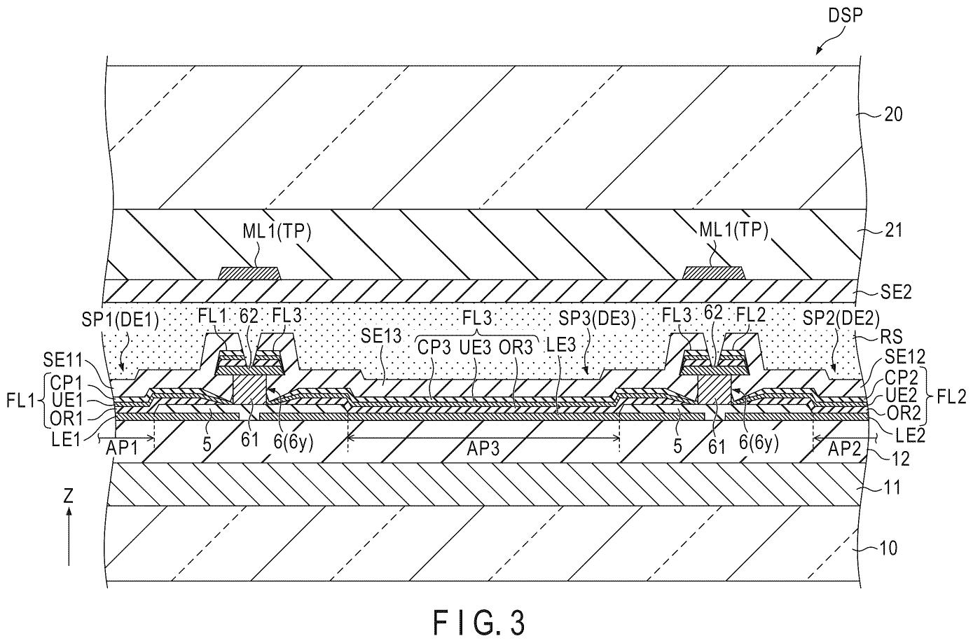

FIG. 3 is a schematic cross-sectional view of the display device DSP along the III-III line of FIG. 2. A circuit layer 11 is provided on the substrate 10 described above. Although not shown in FIG. 3, the circuit layer 11 includes various circuits and lines such as the pixel circuit 1, scanning line GL, signal line SL and power line PL shown in FIG. 1.

The circuit layer 11 is covered with an organic insulating layer 12. The organic insulating layer 12 functions as a planarization film which planarizes the irregularities formed by the circuit layer 11. Although not shown in the section of FIG. 3, the contact holes CH1, CH2 and CH3 described above are provided in the organic insulating layer 12.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5.

The partition 6 includes a conductive lower portion 61 provided on the rib 5 and an upper portion 62 provided on the lower portion 61. The upper portion 62 has a width greater than that of the lower portion 61. By this configuration, in FIG. 3, the both end portions of the upper portion 62 protrude relative to the side surfaces of the lower portion 61. This shape of the partition 6 is called an overhang shape.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. At least parts of the upper electrodes UE1, UE2 and UE3 are in contact with the side surface of the lower portion 61.

In the example of FIG. 3, a cap layer CP1 is provided on the upper electrode UE1. A cap layer CP2 is provided on the upper electrode UE2. A cap layer CP3 is provided on the upper electrode UE3. The cap layers CP1, CP2 and CP3 adjust the optical property of the light emitted from the organic layers OR1, OR2 and OR3, respectively.

In the following explanation, a stacked layer body including the organic layer OR1, the upper electrode UE1 and the cap layer CP1 is called a thin film FL1. A stacked layer body including the organic layer OR2, the upper electrode UE2 and the cap layer CP2 is called a thin film FL2. A stacked layer body including the organic layer OR3, the upper electrode UE3 and the cap layer CP3 is called a thin film FL3.

The thin film FL1 is partly located on the upper portion 62. This portion is spaced apart from, of the thin film FL1, the portion located under the partition 6 (in other words, the portion which constitutes the display element DE1). Similarly, the thin film FL2 is partly located on the upper portion 62. This portion is spaced apart from, of the thin film FL2, the portion located under the partition 6 (in other words, the portion which constitutes the display element DE2). Further, the thin film FL3 is partly located on the upper portion 62. This portion is spaced apart from, of the thin film FL3, the portion located under the partition 6 (in other words, the portion which constitutes the display element DE3).

First sealing layers SE11, SE12 and SE13 are provided in subpixels SP1, SP2 and SP3, respectively. The first sealing layer SE11 continuously covers the thin film FL1 and the partition 6 around subpixel SP1. The first sealing layer SE12 continuously covers the thin film FL2 and the partition 6 around subpixel SP2. The first sealing layer SE13 continuously covers the thin film FL3 and the partition 6 around subpixel SP3.

In the example of FIG. 3, the thin film FL1 and first sealing layer SE11 located on the partition 6 between subpixels SP1 and SP3 are spaced apart from the thin film FL3 and first sealing layer SE13 located on this partition 6. The thin film FL2 and first sealing layer SE12 located on the partition 6 between subpixels SP2 and SP3 are spaced apart from the thin film FL3 and first sealing layer SE13 located on this partition 6.

The first sealing layers SE11, SE12 and SE13 are covered with a resin layer RS. The resin layer RS is covered with a second sealing layer SE2. The resin layer RS and the second sealing layer SE2 are continuously provided in at least the entire display area DA and partly extend in the surrounding area SA as well.

The display device DSP further comprises a cover member 20 which faces the second sealing layer SE2. The cover member 20 and the second sealing layer SE2 are attached to each other by a transparent adhesive layer 21. For the adhesive layer 21, for example, an optical clear adhesive (OCA) can be used.

For example, the cover member 20 is an optical element such as a polarizer, a protective film or a cover glass. The cover member 20 may be a stacked layer body formed by attaching two or more types of elements having different functions, such as an optical element, a protective film and a cover glass, to each other by an adhesive layer.

In the example of FIG. 3, a first metal line ML1 which constitutes a touch panel electrode TP is provided on the second sealing layer SE2. The first metal line ML1 is located above the partition 6 and extends along the partition 6. The first metal line ML1 is covered with the adhesive layer 21.

The organic insulating layer 12 is formed of an organic insulating material. Each of the rib 5, the first sealing layers SE11, SE12 and SE13 and the second sealing layer SE2 is formed of, for example, an inorganic insulating material such as silicon nitride (SiNx), silicon oxide (SiOx) or silicon oxynitride (SiON). Each of the rib 5, the first sealing layers SE11, SE12 and SE13 and the second sealing layer SE2 may be a stacked layer body formed of different types of inorganic insulating materials. The resin layer RS is formed of, for example, a resinous material (organic insulating material) such as epoxy resin or acrylic resin.

Each of the lower electrodes LE1, LE2 and LE3 comprises a reflective layer formed of, for example, silver (Ag), and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

Each of the cap layers CP1, CP2 and CP3 is formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the first sealing layers SE11, SE12 and SE13. It should be noted that at least one of the cap layers CP1, CP2 and CP3 may be omitted.

The first metal line ML1 is formed of a metal material. For example, the first metal line ML1 comprises a stacked structure of titanium (Ti), aluminum (Al) and titanium. However, the first metal line ML1 may comprise a stacked structure of other metal materials or may comprise a single-layer structure.

The lower portion 61 of the partition 6 is formed of, for example, aluminum. The lower portion 61 may be formed of an aluminum alloy such as an aluminum-neodymium alloy (AlNd) or may comprise a multilayer structure consisting of an aluminum layer and an aluminum alloy layer. Further, the lower portion 61 may comprise a thin film formed of a metal material different from aluminum and an aluminum alloy under the aluminum layer or the aluminum alloy layer. This thin film can be formed of, for example, molybdenum (Mo).

For example, the upper portion 62 of the partition 6 comprises a multilayer structure consisting of a thin film formed of a metal material such as titanium and a thin film formed of conductive oxide such as ITO. The upper portion 62 may comprise a single-layer structure of a metal material such as titanium. The upper portion 62 may comprise a single-layer structure of an inorganic insulating material different from the first sealing layers SE11, SE12 and SE13.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer of the organic layer OR1 emits light in a red wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a blue wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

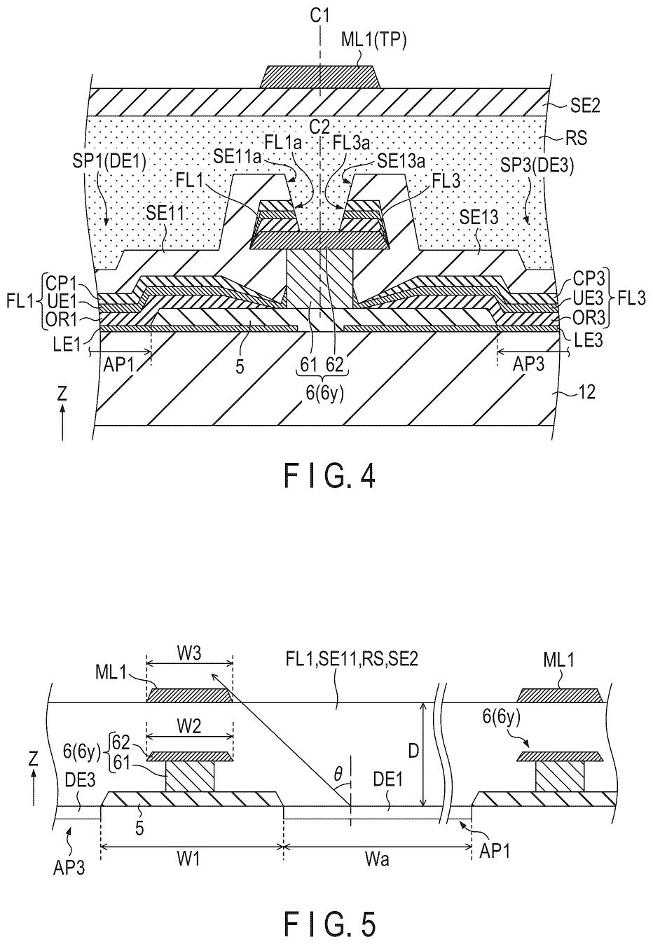

FIG. 4 is a schematic cross-sectional view in which the partition 6 provided in the boundary between subpixels SP1 and SP3 and its vicinity are enlarged. In this figure, the substrate 10, the circuit layer 11, the cover member 20 and the adhesive layer 21 are omitted.

The organic layer OR1, the upper electrode UE1 and the cap layer CP1 are formed by vapor deposition and are patterned with the first sealing layer SE11. An end portion FL1a of the thin film FL1 including the organic layer OR1, the upper electrode UE1 and the cap layer CP1 is located on the upper portion 62. An end portion SE11a of the first sealing layer SE11 is also located on the upper portion 62. The end portion FL1a is not covered with the first sealing layer SE11.

Similarly, the organic layer OR3, the upper electrode UE3 and the cap layer CP3 are formed by vapor deposition and are patterned with the first sealing layer SE13. An end portion FL3a of the thin film FL3 including the organic layer OR3, the upper electrode UE3 and the cap layer CP3 is located on the upper portion 62. An end portion SE13a of the first sealing layer SE13 is also located on the upper portion 62. The end portion FL3a is not covered with the first sealing layer SE13.

The end portion FL1a and the end portion FL3a are spaced apart from each other across an intervening gap. The end portion SE11a and the end portion SE13a are spaced apart from each other across an intervening gap. The resin layer RS is continuously provided in the entire display area DA and covers the end portions FL1a, FL3a, SE11a and SE13a. Further, the gap between the end portion FL1a and the end portion FL3a and the gap between the end portion SE11a and the end portion SE13a are filled with the resin layer RS. The resin layer RS is in contact with the upper portion 62.

The first metal line ML1 faces the upper portion 62 in a third direction Z. For example, the position of center C1 in the width direction of the first metal line ML1 is coincident with the position of center C2 in the width direction of the partition 6. However, center C1 may not be coincident with center C2. It should be noted that the width directions refer to directions orthogonal to the directions in which the first metal line ML1 and the partition 6 extend as seen in plan view. For example, the width direction of each first partition 6x is the second direction Y. The width direction of each second partition 6y is the first direction X.

It should be noted that the configuration of the partition 6 between subpixels SP1 and SP2 and its vicinity and the configuration of the partition 6 between subpixels SP2 and SP3 and its vicinity are similar to the configuration of the example of FIG. 4.

FIG. 5 is a schematic diagram for explaining the sizes of the rib 5, the partition 6, the display element DE1 and the first metal line ML1 and shows a schematic section of the display elements DE1 and DE3 and the rib 5, the partition 6 (second partition 6y) and the first metal line ML1 between the display elements DE1 and DE3.

Here, the width of the display element DE1 is defined as Wa. The width of the rib 5 between the pixel apertures AP1 and AP3 is defined as W1. The width of the upper portion 62 of the partition 6 is defined as W2. The width of the first metal line ML1 is defined as W3. The distance between the display element DE1 and the first metal line ML1 in the third direction Z is defined as D. The angle made by the direction in which the user views the display element DE1 and the normal direction of the display element DE1 is defined as e.

Width W3 needs to be set such that the first metal line ML1 does not block the light emitted from the display element DE1 or the effect on this light is small. For example, in a case where width W1 is 10 μm, and both width W2 and width W3 are 5 μm, and width Wa is 20 μm, and distance D is 3.5 μm, the effect of the first metal line ML1 is not substantially caused when angle θ is in the range of 0° to 35°. When angle θ is approximately 60°, the luminance of the light viewed by the user is decreased by approximately 10% compared to a case where the first metal line ML1 is not provided.

In a case where the first metal line ML1 is not provided, when angle θ is approximately 45°, the luminance is decreased by approximately a half compared to a case where angle θ is 0°. By providing the first metal line ML1, the luminance is further reduced. However, an effect which will be a practical problem is not caused.

In a case where width W3 is great, even if angle θ is less, the effect of the first metal line ML1 is caused, and thus, the reduction in luminance is increased. In a case where width W3 is greater than width W1, the luminance which is obtained when the display element DE1 is viewed from the front side (angle θ=0°) is decreased compared to a case where the first metal line ML1 is not provided, and thus, the display quality of the display device DSP is considerably reduced. In a case where width W3 is equal to width W1, the luminance is decreased by approximately 10% when angle θ is approximately 30°, and the luminance is decreased by approximately 30% when angle θ is approximately 60°.

In consideration of the above matters, width W3 should be desirably less than or equal to width W1 (W3≤W1). More desirably, width W3 should be less than or equal to width W2 (W3≤W2). For example, width W1 is 5 μm to 25 μm. The thickness of the resin layer RS is less than or equal to 2 μm. The thickness of the second sealing layer SE2 is less than or equal to 1 μm.

When each pixel PX is large, the area affected by the first metal line ML1 is relatively small. For example, in a case of a 55-inch display device with 3840×2160 pixels, the size of each pixel PX is approximately 315 μm. At this time, in a case where width Wa of the display element DE1 is 80 μm, and width W1 of the rib 5 is 5 μm, and angle θ is 60°, and distance D is 5 μm, when width W3 is less than or equal to width W1, the reduction in luminance by the first metal line ML1 is suppressed within 10%.

A configuration similar to the configuration explained with reference to FIG. 4 and FIG. 5 can be applied to the display element DE2 and the rib 5, partition 6 and first metal line ML1 provided around the display element DE2.

Now, this specification explains a structure which could be applied to the surrounding area SA.

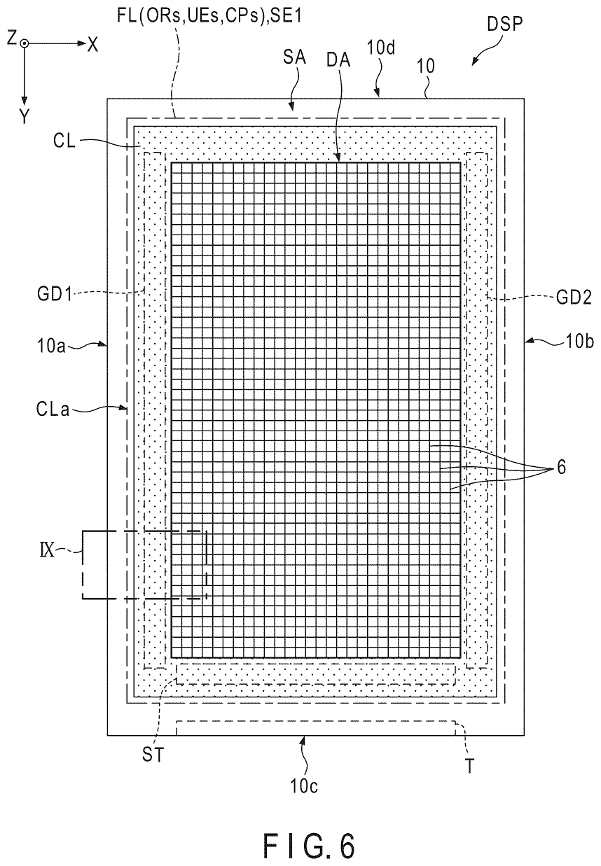

FIG. 6 is a schematic plan view of the display device DSP. The display device DSP comprises, as elements provided in the surrounding area SA, a first gate drive circuit GD1, a second gate drive circuit GD2, a selector circuit ST and a terminal portion T. The first gate drive circuit GD1, the second gate drive circuit GD2 and the selector circuit ST are examples of drive circuits which supply signals to the pixel circuits 1, and are included in the circuit layer 11 shown in FIG. 3.

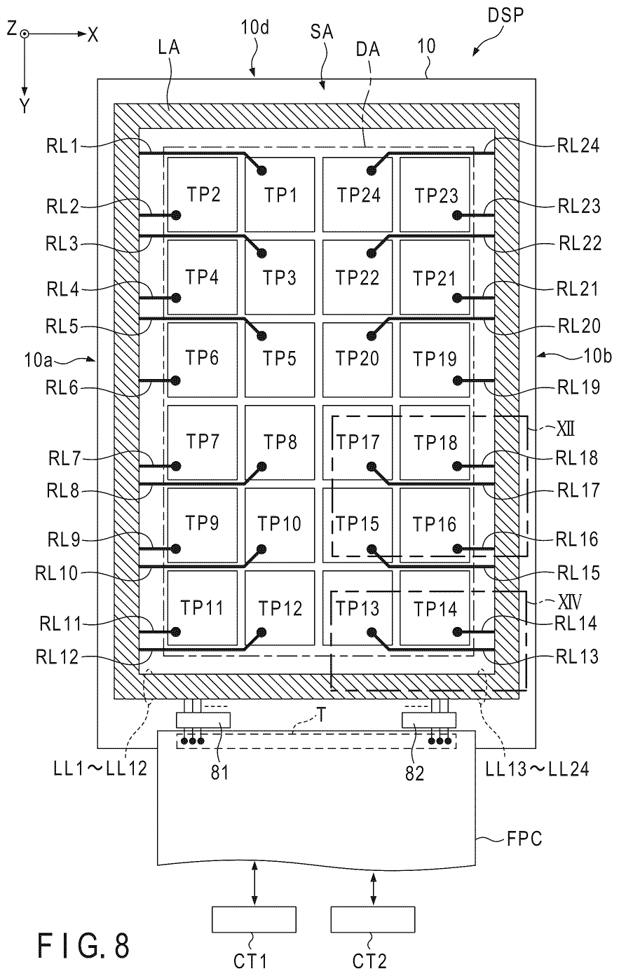

The first gate drive circuit GD1 and the second gate drive circuit GD2 supply scanning signals to the scanning lines GL shown in FIG. 1. For example, a flexible printed circuit FPC (see FIG. 8) is connected to the terminal portion T. The selector circuit ST supplies video signals input from the flexible printed circuit FPC to the signal lines SL shown in FIG. 1.

The substrate 10 comprises end portions 10a, 10b, 10c and 10d. The end portions 10a and 10b extend parallel to the second direction Y. The end portions 10c and 10d extend parallel to the first direction X.

In the example of FIG. 6, the first gate drive circuit GD1 is provided between the display area DA and the end portion 10a. The second gate drive circuit GD2 is provided between the display area DA and the end portion 10b. The selector circuit ST and the terminal portion T are provided between the display area DA and the end portion 10c.

Further, the display device DSP comprises a conductive layer CL (the portion shown by the dotted pattern) provided in the surrounding area SA. In the example of FIG. 6, the conductive layer CL surrounds the display area DA.

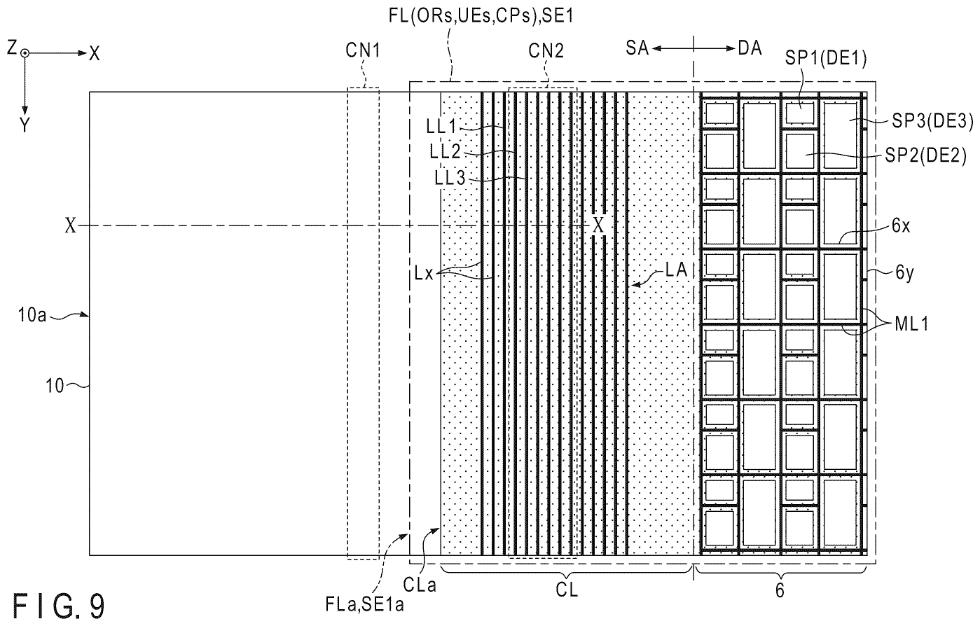

The conductive layer CL is connected to the partition 6 provided in the display area DA (see FIG. 9). The conductive layer CL overlaps the first gate drive circuit GD1, the second gate drive circuit GD2 and the selector circuit ST as seen in plan view.

It should be noted that the conductive layer CL may not necessarily have a shape surrounding the display area DA. For example, the conductive layer CL may not be provided between the display area DA and the end portion 10c or between the display area DA and the end portion 10d.

An organic layer ORs, an upper electrode UEs, a cap layer CPs and a first sealing layer SE1 are provided in the surrounding area SA. The organic layer ORs is formed of the same material by the same manufacturing process as one of the organic layers OR1, OR2 and OR3. The upper electrode UEs is formed of the same material by the same manufacturing process as one of the upper electrodes UE1, UE2 and UE3. The cap layer CPs is formed of the same material by the same manufacturing process as one of the cap layers CP1, CP2 and CP3. The first sealing layer SE1 is formed of the same material by the same manufacturing process as one of the sealing layers SE11, SE12 and SE13.

For example, the organic layer ORs, the upper electrode UEs, the cap layer CPs and the first sealing layer SE1 are formed of the same material by the same manufacturing process as the organic layer OR3, the upper electrode UE3, the cap layer CP3 and the first sealing layer SE13, respectively.

In the following explanation, the stacked layer body including the organic layer ORs, the upper electrode UEs and the cap layer CPs is called a thin film FL. The thin film FL and the first sealing layer SE1 overlap the conductive layer CL as seen in plan view.

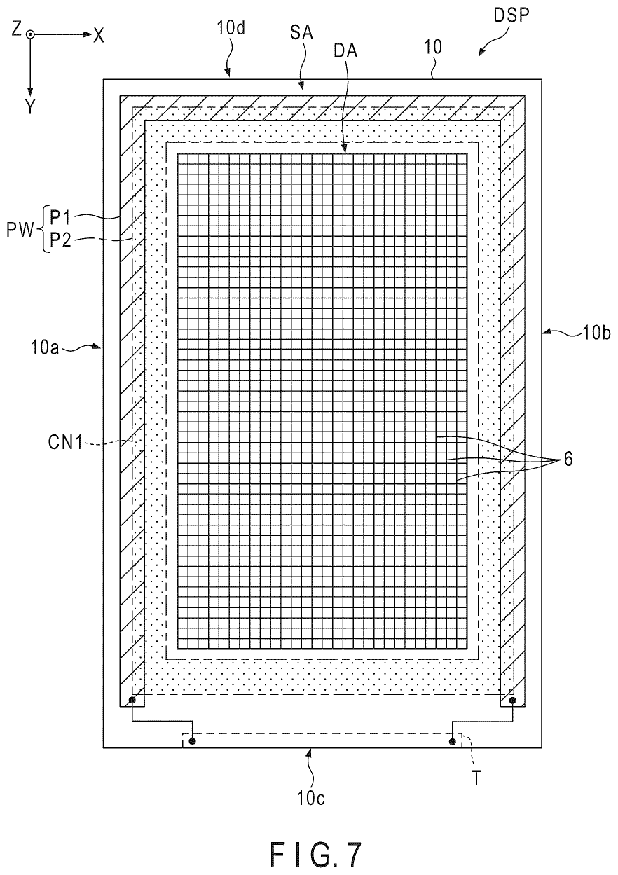

FIG. 7 is a schematic plan view showing other elements provided in the surrounding area SA. A feed line PW is provided in the surrounding area SA. The feed line PW includes a first portion P1 (the portion shown by the diagonal pattern) and a second portion P2 (the portion shown by the dotted pattern).

In the example of FIG. 7, the second portion P2 surrounds the display area DA. The first portion P1 extends between the display area DA and the end portions 10a, 10b and 10d. However, the first portion P1 is not provided between the display area DA and the end portion 10c. As another example, the first portion P1 may surround the display area DA.

The first portion P1 and the second portion P2 partly overlap each other. The first portion P1 is electrically connected to the terminal portion T. Common voltage is applied to the first portion P1 through the terminal portion T. Further, the common voltage of the first portion P1 is applied to the second portion P2.

FIG. 8 is a schematic plan view showing elements for realizing functions related to a touch panel. A plurality of touch panel electrodes TP are provided in the display area DA. In the example of FIG. 8, 24 (6 rows×4 columns) touch panel electrodes TP1 to TP24 are arranged in matrix. The touch panel electrodes TP1 to TP12 are located on the left half side of the display area DA. The touch panel electrodes TP13 to TP24 are located on the right half side of the display area DA. It should be noted that the number or layout form of the touch panel electrodes TP is not limited to this example.

A line area LA for connecting the touch panel electrodes TP and the terminal portion T is provided in the surrounding area SA. The line area LA includes the same number of leads LL (LL1 to LL24) as the touch panel electrodes TP and surrounds the display area DA.

The leads LL1 to LL12 connected to the touch panel electrodes TP1 to TP12, respectively, are provided so as to pass through the area between the display area DA and the end portion 10a. The leads LL13 to LL24 connected to the touch panel electrodes TP13 to TP24, respectively, are provided so as to pass through the area between the display area DA and the end portion 10b.

The line area LA is connected to the touch panel electrodes TP1 to TP24 by relay lines RL (RL1 to RL24). Specifically, the touch panel electrodes TP1 to TP12 are connected to the leads LL1 to LL12 via the relay lines RL1 to RL12, respectively. The touch panel electrodes TP13 to TP24 are connected to the leads LL13 to LL24 via the relay lines RL13 to RL24, respectively.

The leads LL1 to LL12 are connected to the terminal portion T via a connection portion 81. The leads LL13 to LL24 are connected to the terminal portion T via a connection portion 82.

For example, the touch panel electrodes TP1 to TP12, the leads LL1 to LL12, the relay lines RL1 to RL12 and the connection portion 81 and the touch panel electrodes TP13 to TP24, the leads LL13 to LL24, the relay lines RL13 to RL24 and the connection portion 82 have a line-symmetric shape with respect to the center line of the display device DSP in the first direction X.

An end of the flexible printed circuit FPC is connected to the terminal portion T via, for example, a conductive adhesive material. The other end of the flexible printed circuit FPC is connected to the substrate of an electronic device on which the display device DSP is mounted. The video signals and power necessary to display images are supplied to the display device DSP through the flexible printed circuit FPC.

The display device DSP further comprises a display controller CT1 which performs control related to image display and a detection controller CT2 which performs control related to touch detection. These controllers CT1 and CT2 consist of, for example, ICs, and are mounted on the flexible printed circuit FPC. The controllers CT1 and CT2 may be mounted on separate flexible printed circuits, and these flexible printed circuits may be connected to the terminal portion T.

The present embodiment assumes a case where the touch panel electrodes TP1 to TP24 constitute a capacitive touch panel. For example, when an object such as a finger of a user contacts or approaches the display area DA, the detection controller CT2 specifies the position contacted or approached by the object based on the change generated in the capacitance of the touch panel electrodes TP1 to TP24 at the time of the contact or approach. This system is called self capacitive sensing.

It should be noted that mutual capacitive sensing may be applied as the system for detecting objects. In this case, a drive electrode is provided in the display area DA in addition to the touch panel electrodes TP1 to TP24. When an object contacts or approaches the display area DA, the electric field between the touch panel electrodes TP1 to TP24 and the drive electrode is affected by the object, and thus, the capacitance between the touch panel electrodes TP1 to TP24 and the drive electrode changes. The detection controller CT2 specifies the position contacted or approached by the object based on the change in the capacitance.

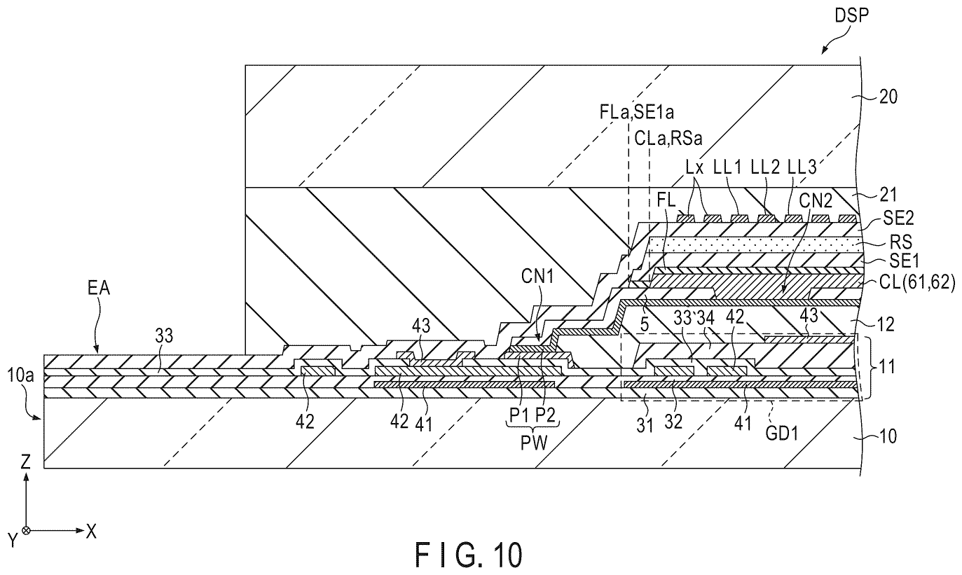

FIG. 9 is an enlarged view of the area surrounded by the chained frame IX of FIG. 6. FIG. 10 is a schematic cross-sectional view of the display device DSP along the X-X line of FIG. 9. In FIG. 9, the dotted area corresponds to the conductive layer CL and the partition 6 (the first partitions 6x and the second partitions 6y). The conductive layer CL and the partition 6 are integrally formed of the same material by the same manufacturing process.

In the example of FIG. 10, the circuit layer 11 comprises inorganic insulating layers 31, 32 and 33, an organic insulating layer 34, and metal layers 41, 42 and 43. The inorganic insulating layer 31 covers the substrate 10. The metal layer 41 is provided on the inorganic insulating layer 31 and is covered with the inorganic insulating layer 32. The metal layer 42 is provided on the inorganic insulating layer 32 and is covered with the inorganic insulating layer 33. The organic insulating layer 34 is provided on the inorganic insulating layer 33. The metal layer 43 is provided on the organic insulating layer 34 and is covered with the organic insulating layer 12.

Each of the inorganic insulating layers 31, 32 and 33 is formed of, for example, an inorganic material such as silicon nitride or silicon oxide. For example, each of the metal layers 41, 42 and 43 comprises a single-layer structure of a metal material such as molybdenum (Mo), tungsten (W), molybdenum tungsten alloy (MoW), aluminum (Al) or copper (Cu), or a multilayer structure of these metal materials.

The first gate drive circuit GD1 consists of the metal layers 41, 42 and 43 and a semiconductor layer. Similarly, the second gate drive circuit GD2 and selector circuit ST shown in FIG. 6 and the pixel circuit 1 shown in FIG. 1 consist of the metal layers 41, 42 and 43 and a semiconductor layer. The scanning line GL shown in FIG. 1 consists of the metal layer 41. The signal line SL shown in FIG. 1 consists of the metal layer 42.

The configuration of the circuit layer 11 is not limited to the example shown in FIG. 10. For example, the circuit layer 11 may comprise more inorganic insulating layers and metal layers. The circuit layer 11 may not comprise the organic insulating layer 34.

The conductive layer CL covers the rib 5 in the surrounding area SA. The conductive layer CL includes a lower portion 61 and an upper portion 62 in a manner similar to that of the partition 6 shown in FIG. 3 and FIG. 4.

The second portion P2 of the feed line PW is largely provided on the organic insulating layer 12 and covered with the rib 5. For example, the second portion P2 is formed of the same material by the same manufacturing process as the lower electrodes LE1, LE2 and LE3.

The second portion P2 is connected to the first portion P1 in a contact portion CN1 and is connected to the conductive layer CL in a contact portion CN2. By this configuration, common voltage is applied to the conductive layer CL via the first portion P1 and the second portion P2. Further, the common voltage of the conductive layer CL is applied to the partition 6 and the upper electrodes UE1, UE2 and UE3 of the display area DA.

In the contact portion CN1, the second portion P2 is in contact with the first portion P1. The contact portion CN1 corresponds to, for example, the area in which the first portion P1 and the second portion P2 overlap each other in the plan view of FIG. 7. In the example of FIG. 10, the first portion P1 consists of the metal layer 43. The first portion P1 may consist of the metal layer 41 or the metal layer 42 or may consist of two or more of the metal layers 41, 42 and 43.

As shown in FIG. 10, an aperture is formed in the rib 5 in the contact portion CN2. The conductive layer CL is in contact with the second portion P2 through this aperture. The aperture of the rib 5 may range over the entire part of the contact portion CN2 shown in FIG. 9. The rib 5 may comprise a plurality of apertures dispersed in the contact portion CN2.

As shown in FIG. 9, the contact portion CN2 is located between the first contact portion CN1 and the display area DA in plan view. An end portion CLa of the conductive layer CL is located between the contact portion CN1 and the contact portion CN2 as seen in plan view.

In FIG. 9, the area in which the thin film FL and the first sealing layer SE1 are provided is shown by chain lines. In FIG. 10, the thin film FL is shown as one layer. In practice, in the thin film FL, the upper electrode UEs covers the organic layer ORs, and the cap layer CPs covers the upper electrode UEs. The first sealing layer SE1 covers the thin film FL.

As shown in FIG. 10, the thin film FL covers the conductive layer CL. As shown in FIG. 9, the position of an end portion FLa of the thin film FL is substantially coincident with that of an end portion SE1a of the first sealing layer SE1 in plan view. The end portions FLa and SE1a are located between the end portion CLa of the conductive layer CL and the contact portion CN1.

As shown in FIG. 10, the resin layer RS and the second sealing layer SE2 are formed in the surrounding area SA as well. For example, an end portion RSa of the resin layer RS is located on the display area DA side relative to the end portion FLa of the thin film FL and the end portion SE1a of the first sealing layer SE1. In the example of FIG. 10, the end portion RSa is located near the end portion CLa of the conductive layer CL. However, the configuration is not limited to this example.

In the example of FIG. 10, the second sealing layer SE2 is provided in the entire surrounding area SA. However, for example, the second sealing layer SE2 may not be provided near the end portion 10a, 10b, 10c or 10d of the substrate 10. The second sealing layer SE2 entirely covers the resin layer RS. Further, the second sealing layer SE2 is in contact with the first sealing layer SE1, the rib 5, the inorganic insulating layer 33, etc. The end portion RSa of the resin layer RS is covered with the first sealing layer SE1 and the second sealing layer SE2. The end portion FLa of the thin film FL is covered with the rib 5 and the second sealing layer SE2.

In the example of FIG. 9, the first metal line ML1 which constitutes the touch panel electrode TP extends along the partition 6 and has a grating shape as a whole. Specifically, the first metal line ML1 overlaps the first partitions 6x and the second partitions 6y and surrounds each of subpixels SP1, SP2 and SP3 (the display elements DE1, DE2 and DE3). It should be noted that the first metal line ML1 does not have to individually surround subpixel SP1, SP2 or SP3.

The line area LA overlaps the conductive layer CL as seen in plan view. The leads LL1 to LL12 are arranged in order toward the display area DA. At least one line Lx is provided on the external side of the leads LL1 to LL12. These lines Lx include, for example, a ground line to which reference potential is supplied. The lines Lx may include a line which supplies signals for touch detection.

As shown in FIG. 10, the leads LL1 to LL12 and the lines Lx are provided on the second sealing layer SE2. The leads LL1 to LL12 and the lines Lx are covered with the adhesive layer 21. The substrate 10 comprises an exposed area EA which does not face the cover member 20 near the end portion 10a. The exposed area EA is not covered with the adhesive layer 21.

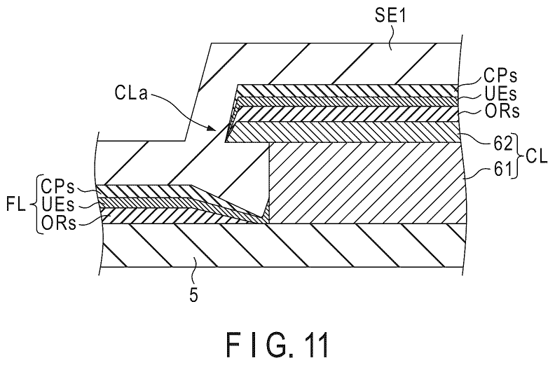

FIG. 11 is a schematic cross-sectional view of the vicinity of the end portion CLa of the conductive layer CL. The conductive layer CL comprises the lower portion 61 and the upper portion 62 in a manner similar to that of the partition 6 shown in FIG. 4. In the end portion CLa, the upper portion 62 protrudes relative to a side surface of the lower portion 61. In other words, the shape of the conductive layer CL in the end portion CLa is an overhang shape in a manner similar to that of the partition 6.

When the thin film FL (the organic layer ORs, the upper electrode UEs and the cap layer CPs) is formed on the conductive layer CL having this shape, as shown in FIG. 11, the thin film FL is divided in the end portion CLa. The first sealing layer SE1 covers the thin film FL located on the upper and lower sides of the conductive layer CL and also covers a side surface of the lower portion 61.

In FIG. 9 and FIG. 10, this specification focuses attention on the structure between the display area DA and the end portion 10a of the substrate 10. However, a similar structure can be applied to the structure between the display area DA and the end portion 10b. The leads LL13 to LL24 are provided on the second sealing layer SE2 and are covered with the adhesive layer 21 in a manner similar to that of the leads LL1 to LL12. For example, the leads LL1 to LL24 and the lines Lx are formed of the same material by the same process as the first metal line ML1.

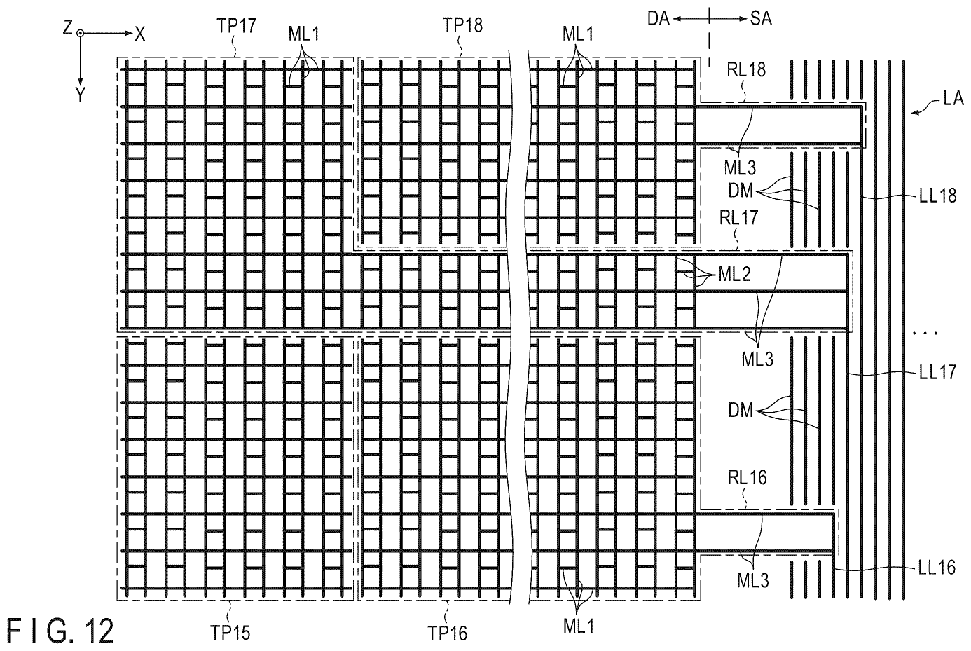

FIG. 12 is a schematic plan view of the area surrounded by the chained frame XII of FIG. 8 and shows an example of a configuration which could be applied to the touch panel electrodes TP15 to TP18 and the relay lines RL16 to RL18.

The relay line RL17 includes a second metal line ML2 provided in the display area DA and third metal lines ML3 provided in the surrounding area SA. The second metal line ML2 is located above the partition 6 in a manner similar to that of the first metal line ML1 constituting the touch panel electrode TP17, and extends along the partition 6. The second metal line ML2 surrounds each of subpixels SP1, SP2 and SP3 and has a grating shape as a whole. For example, the second metal line ML2 and the third metal lines ML3 are formed of the same material by the same manufacturing process as the first metal line ML1. Specifically, the second metal line ML2 and the third metal lines ML3 are located on the second sealing layer SE2 and are covered with the adhesive layer 21.

For example, the width of the second metal line ML2 is the same as width W3 of the first metal line ML1 explained with reference to FIG. 5. Specifically, the width of the second metal line ML2 is less than or equal to width W1 of the rib 5 and should be desirably less than or equal to width W2 of the upper portion 62.

Of the relay line RL17, the portion consisting of the second metal line ML2 passes through the area between the touch panel electrodes TP16 and TP18 and is connected to the third metal lines ML3. The third metal lines ML3 linearly extend in, for example, the first direction X, and are connected to the lead LL17. In the example of FIG. 12, the relay line RL17 includes three third metal lines ML3 which are arranged in the second direction Y.

Each of the relay lines RL16 and RL18 includes the third metal lines ML3 and does not include the second metal line ML2. In the example of FIG. 12, each of the relay lines RL16 and RL18 includes two third metal lines ML3 which are arranged in the second direction Y. In other words, in this example, the number of third metal lines ML3 included in each of the relay lines RL16 and RL18 is less than that of third metal lines ML3 included in the relay line RL17.

The line area LA includes a plurality of electrically floating dummy lines DM. In the example of FIG. 12, the dummy lines DM are provided between the leads LL16, LL17 and LL18 and the display area DA. The dummy lines DM are provided with the same pitch as the leads LL16, LL17 and LL18 and extend parallel to the leads LL16, LL17 and LL18.

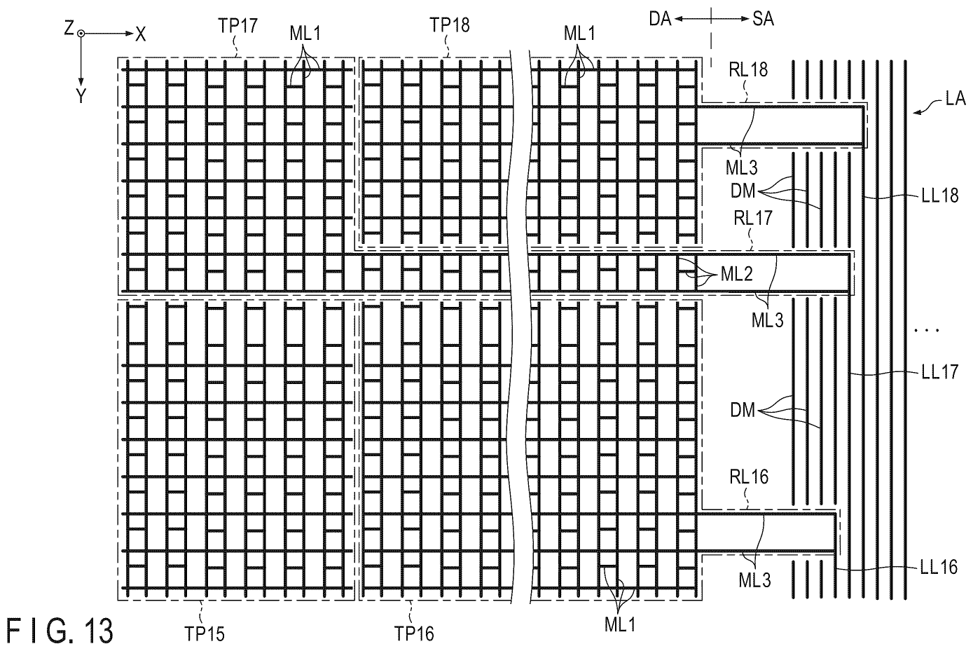

FIG. 13 is a schematic plan view showing another example of a configuration which could be applied to the touch panel electrodes TP15 to TP18 and the relay lines RL16 to RL18. In the example of this figure, the relay line R17 includes two third metal lines ML3. Further, the width of, of the relay line RL17, the portion which consists of the second metal line ML2 in the second direction Y is less than that of the example of FIG. 12.

In addition to these examples of FIG. 12 and FIG. 13, various configurations could be applied to the relay lines RL16 to RL18. For example, each of the relay lines RL16 to RL18 may include more third metal lines ML3.

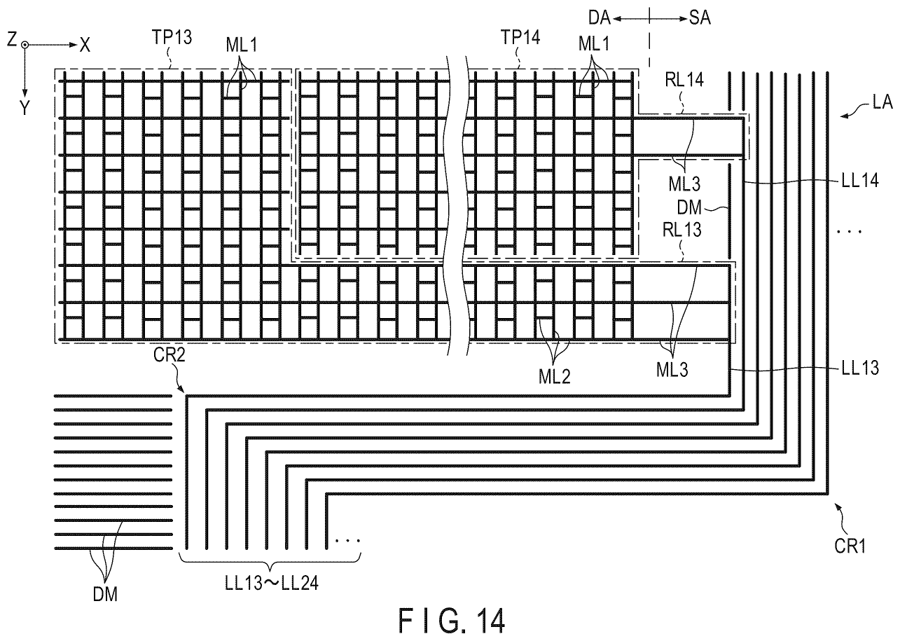

FIG. 14 is a schematic plan view of the area surrounded by the chained frame XIV of FIG. 8 and shows an example of a configuration which could be applied to the touch panel electrodes TP13 and TP14, the relay lines RL13 and RL14 and the vicinity of the electrodes and the lines.

The relay line RL13 includes the second metal line ML2 and the third metal lines ML3 in a manner similar to that of the relay line RL17. Of the relay line RL13, the portion which consists of the second metal line ML2 passes through the area between the touch panel electrode TP14 and the surrounding area SA, extends in the first direction X and is connected to the lead LL13.

In the example of FIG. 14, the relay line RL13 includes three third metal lines ML3 which are arranged in the second direction Y, and the relay line RL14 includes two third metal lines ML3 which are arranged in the second direction Y. The number of third metal lines ML3 included in the relay line RL13 may be two in the same manner as the relay line RL17 shown in FIG. 13 or may be four or more. In addition, the number of third metal lines ML3 included in the relay line RL14 is not limited to two.

In the example of FIG. 14, the leads LL13 to LL24 are bent at 90° in two corner portions CR1 and CR2. On the upper side of the figure relative to the corner portion CR1, the leads LL13 to LL24 extend parallel to the second direction Y. Between the corner portions CR1 and CR2, the leads LL13 to LL24 extend parallel to the first direction X. On the lower side of the figure relative to the corner portion CR2, the leads LL13 to LL24 extend parallel to the second direction Y. The dummy lines DM are provided in the area located on the lower side of the display area DA in the figure (in other words, the area between the display area DA and the end portion 10c) as well. These dummy lines DM extend parallel to the first direction X.

FIG. 12 to FIG. 14 show configurations which could be applied to the touch panel electrodes TP13 to TP18 and the relay lines RL13, RL14 and RL16 to RL18. Similar configurations can be applied to the other touch panel electrodes TP and relay lines RL. In other words, each touch panel electrode TP which is adjacent to the surrounding area SA in the first direction X is connected to a lead LL by a relay line RL consisting of the third metal lines ML3. Each touch panel electrode TP which is provided such that, between the touch panel electrode TP and the surrounding area SA, another touch panel electrode TP is interposed in the first direction X, is connected to a lead LL by a relay line RL consisting of the second metal line ML2 and the third metal lines ML3.

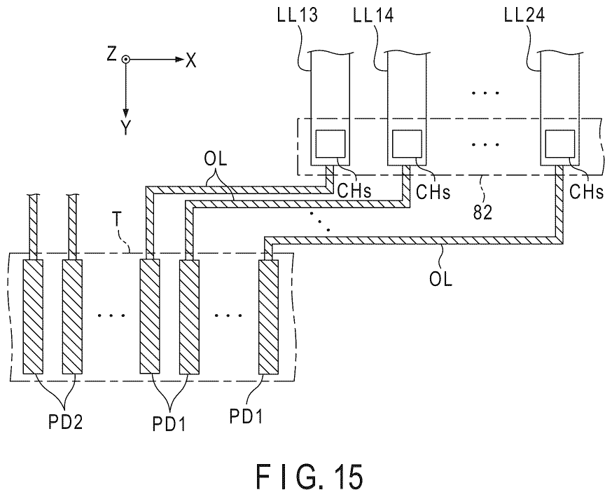

FIG. 15 is a schematic plan view of the leads LL13 to LL24, the connection portion 82 and the terminal portion T. The terminal portion T comprises a plurality of first pads PD1 which are arranged in the first direction X. Output lines OL are connected to the first pads PD1, respectively.

The leads LL13 to LL24 are provided in a layer different from that of the output lines OL. In the connection portion 82, the leads LL13 to LL24 are connected to the output lines OL via contact holes CHs.

The terminal portion T also comprises second pads PD2 for supplying signals to elements related to image display, such as the selector circuit ST. The second pads PD2 are arranged in the first direction X with the first pads PD1.

It should be noted that the configuration for connecting the leads LL1 to LL12 to the terminal portion T via the connection portion 81 is similar to that of the example of FIG. 15.

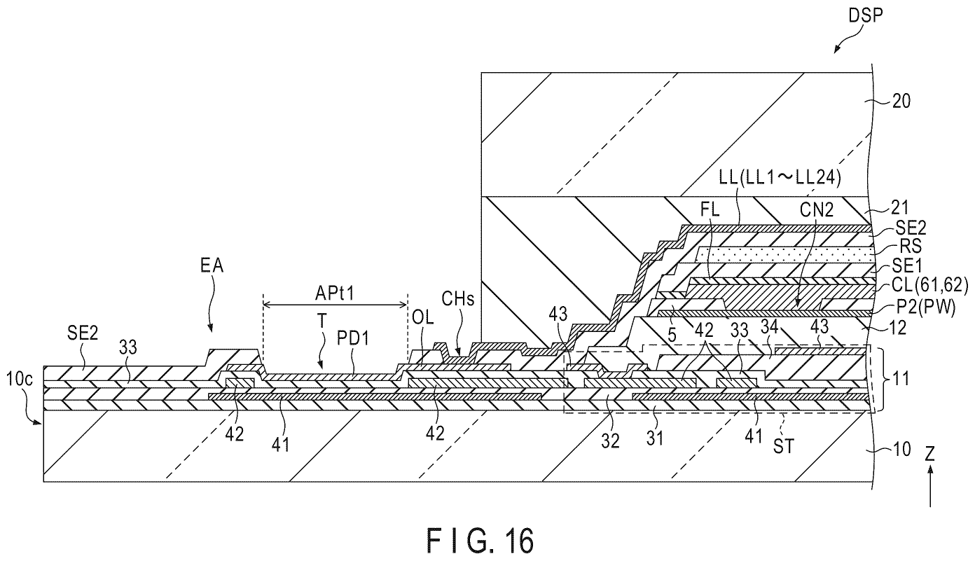

FIG. 16 is a schematic cross-sectional view of the surrounding area SA including the first pad PD1 and a lead LL. The configuration shown in this figure can be also applied to the connection structure between any of the leads LL1 to LL24 and the first pad PD1. The first pad PD1 and the output line OL are integrally formed by, for example, the metal layer 43. It should be noted that the first pad PD1 and the output line OL may be formed by different metal layers.

The terminal portion T is provided in the exposed area EA. Thus, the first pad PD1 is exposed from the adhesive layer 21. The rim of the first pad PD1 is covered with the second sealing layer SE2. The first pad PD1 is exposed from the second sealing layer SE2 through an aperture APt1 provided in the second sealing layer SE2. Although omitted in FIG. 16, the first pad PD1 is connected to the flexible printed circuit FPC described above.

The contact hole CHs penetrates the second sealing layer SE2. The output line OL and the lead LL are connected to each other via the contact hole CHs. A large part of the lead LL is covered with the adhesive layer 21 and faces the cover member 20. In the example of FIG. 16, the lead LL located in the contact hole CHs is exposed from the adhesive layer 21. As another example, the lead LL may be entirely covered with the adhesive layer 21.

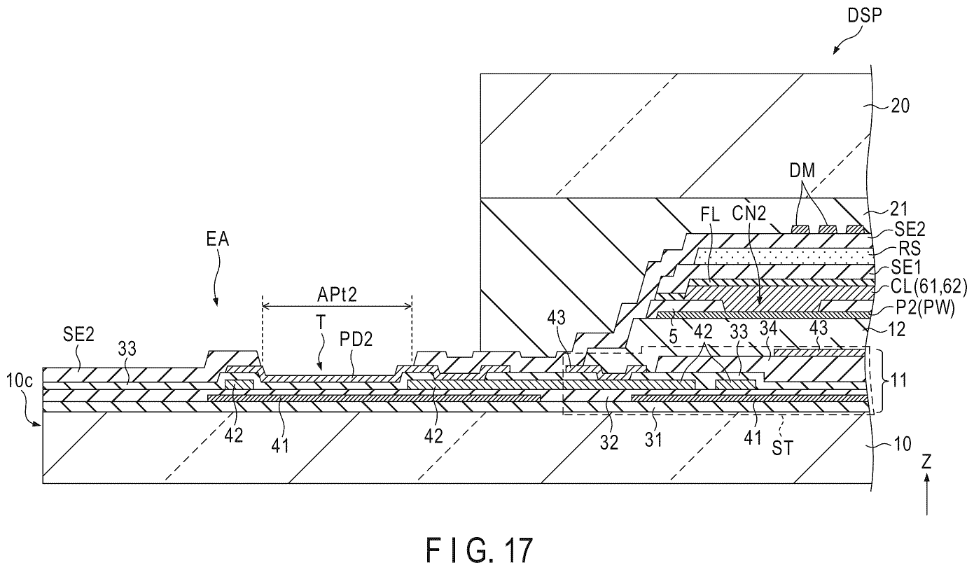

FIG. 17 is a schematic cross-sectional view of the surrounding area SA including the second pad PD2. The second pad PD2 is formed by the metal layer 43 in a manner similar to that of the first pad PD1.

The second pad PD2 is exposed from the second sealing layer SE2 through an aperture APt2 provided in the second sealing layer SE2. Although omitted in FIG. 17, the second pad PD2 is connected to the flexible printed circuit FPC described above.

In the example of FIG. 17, the dummy lines DM are provided on the second sealing layer SE2. The dummy lines DM are covered with the adhesive layer 21.

To manufacture the display device DSP, first, the circuit layer 11 including the pixel circuit 1, the gate drive circuits GD1 and GD2, the selector circuit CT, the feed line PW and the terminal portion T is formed on the substrate 10. After the formation of the circuit layer 11, the organic insulating layer 12 is formed on the circuit layer 11.

Subsequently, the lower electrodes LE1, LE2 and LE3 are formed. The rib 5 is formed on them. Further, the partition 6 and the conductive layer CL are formed.

Subsequently, the thin film FL1 including the organic layer OR1, the upper electrode UE1 and the cap layer CP1 and the first sealing layer SE11 are formed in subpixel SP1. The thin film FL2 including the organic layer OR2, the upper electrode UE2 and the cap layer CP2 and the first sealing layer SE12 are formed in subpixel SP2. The thin film FL3 including the organic layer OR3, the upper electrode UE3 and the cap layer CP3 and the first sealing layer SE13 are formed in subpixel SP3. Although the formation order of the thin films FL1, FL2 and FL3 is not particularly limited, for example, the thin film FL3 is formed firstly, and the thin film FL2 is formed secondly, and the thin film FL1 is formed lastly.

The layers (the organic layer, upper electrode and cap layer) constituting each of the thin films FL1, FL2 and FL3 are formed by, for example, vapor deposition. The first sealing layers SE11, SE12 and SE13 are formed by, for example, chemical vapor deposition (CVD).

The thin film FL (the organic layer ORs, the upper electrode UEs and the cap layer CPs) and the first sealing layer SE1 in the surrounding area SA can be formed of the same materials by the same processes as, for example, the thin film FL3 and the first sealing layer SE13. The thin films FL and FL3 and the first sealing layers SE1 and SE13 are patterned by the same photolithographic process. Thus, as shown in FIG. 10, the end portion FLa of the thin film FL is aligned with the end portion SE1a of the first sealing layer SE1.

After the formation of the thin film FL and the first sealing layer SE1, the resin layer RS is formed. The resin layer RS is formed by, for example, a printing method. However, the resin layer RS may be formed by another method such as an ink-jet method. To prevent the expansion to the circumference, the viscosity of the resin layer RS before cured should be preferably increased. To form this resin layer RS having a high viscosity, a printing method is suitable.

After the formation of the resin layer RS, the second sealing layer SE2 is formed. The second sealing layer SE2 is firstly formed in the entire substrate 10 and is patterned by a photolithographic process. By this photolithographic process, the apertures APt1 and APt2 and the contact hole CHs are formed.

Subsequently, the first metal line ML1, the second metal line ML2, the third metal lines ML3, the leads LL and the dummy lines DM are formed. These lines are obtained by patterning a metal film by the same photolithographic process. At this time, if the arrangement density of the resist formed in the portion in which the metal film should remain largely changes in part, the progress of the etching of the metal film may become nonuniform, and thus, there is a possibility that lead lines LL having a desired shape, etc., cannot be obtained. The dummy lines DM contribute to the correction of the nonuniformity. By providing the dummy lines DM in an area in which the metal line ML1, ML2 or ML3 or the leads LL are not provided, excessive etching for the metal lines ML1, ML2 and ML3 and the leads LL can be prevented.

After the formation of the metal lines ML1, ML2 and ML3, the leads LL and the dummy lines DM, the cover member 20 is attached by the adhesive layer 21. Further, the flexible printed circuit FPC is connected to the terminal portion T. In this manner, the display device DSP is completed.

In the present embodiment described above, the thin films FL1, FL2 and FL3 provided in the display area DA are individually sealed by the partition 6 and the first sealing layers SE11, SE12 and SE13, respectively. Moreover, the resin layer RS covers the first sealing layers SE11, SE12 and SE13, and the second sealing layer SE2 covers the resin layer RS. This configuration satisfactorily prevents moisture from entering the thin films FL1, FL2 and FL3 and further entering the resin layer RS located on them. Thus, the display device DSP having an excellent resistance to moisture can be obtained.

Further, in the present embodiment, the first metal line ML1 constituting each touch panel electrode TP is located above the partition 6 and extends along the partition 6. In this configuration, the light emitted from the display elements DE1, DE2 and DE3 is not easily blocked by the first metal line ML1. In this manner, the display quality can be improved while imparting the function of touch detection to the display device DSP.

As explained with reference to FIG. 5, in a case where width W3 of the first metal line ML1 is less than or equal to width W1 of the rib 5, and further less than or equal to width W2 of the upper portion 62, even when the display area DA is obliquely viewed, the reduction in luminance is prevented. Thus, the display quality is further improved.

As shown in FIG. 12 and FIG. 13, when the relay line RL partially consists of the second metal line ML2 similar to the first metal line ML1, the reduction in display quality by the relay line RL can be prevented. If, of the relay line RL, the portion located in the display area DA consists of a metal line having a width or pattern different from that of the first metal line ML1, the nonuniformity in luminance could be caused by the relay line RL. To the contrary, as shown in the examples of FIG. 12 to FIG. 14, when the second metal line ML2 has a grating shape similar to that of the first metal line ML1 and further has a width equal to the first metal line ML1, the luminance can be made uniform in the entire display area DA.

In the present embodiment, the end portion FLa of the thin film FL provided in the surrounding area SA is covered with the second sealing layer SE2. This configuration can prevent moisture from entering the surrounding circuits through the thin film FL.

Moreover, in the present embodiment, as shown in FIG. 11, the thin film FL is divided by the end portion CLa of the conductive layer CL. This configuration further assuredly prevents moisture penetration through the thin film FL.

The configuration disclosed in the present embodiment could be modified in various ways. Some modified examples are disclosed below.

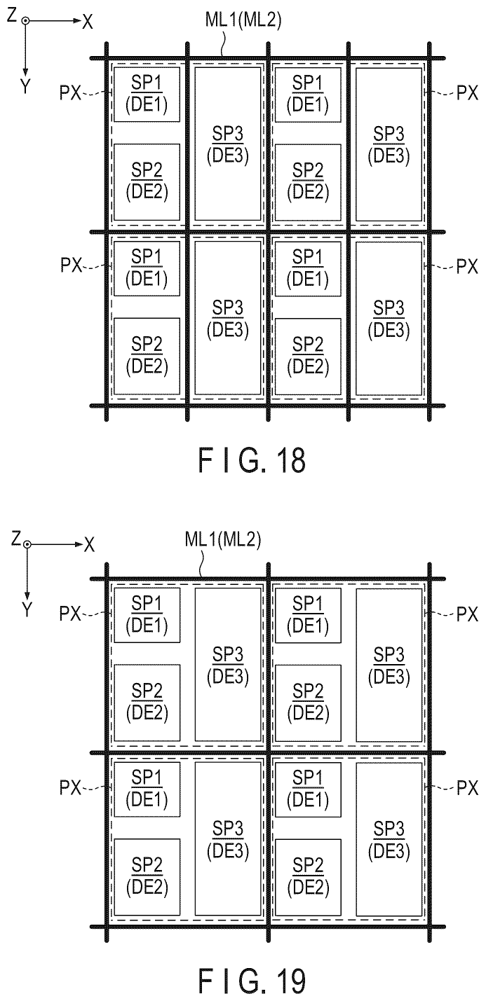

FIG. 18 is a schematic plan view of pixels PX and the first metal line ML1 according to a first modified example. Each pixel PX of the first modified example includes subpixels SP1, SP2 and SP3 (the display elements DE1, DE2 and DE3) arranged in line with the same layout as FIG. 2.

In the first modified example, the first metal line ML1 is not provided between subpixels SP1 and SP2 included in each pixel PX. The first metal line ML1 is provided between subpixels SP1 and SP2 included in different pixels PX. A similar configuration can be applied to the second metal line ML2.

FIG. 19 is a schematic plan view of pixels PX and the first metal line ML1 according to a second modified example. Each pixel PX of the second modified example includes subpixels SP1, SP2 and SP3 arranged in line with the same layout as FIG. 2.

In the second modified example, the first metal line ML1 is provided between adjacent pixels PX, and the first metal line ML1 is not provided between subpixels SP1, SP2 and SP3 included in each pixel PX. A similar configuration can be applied to the second metal line ML2.

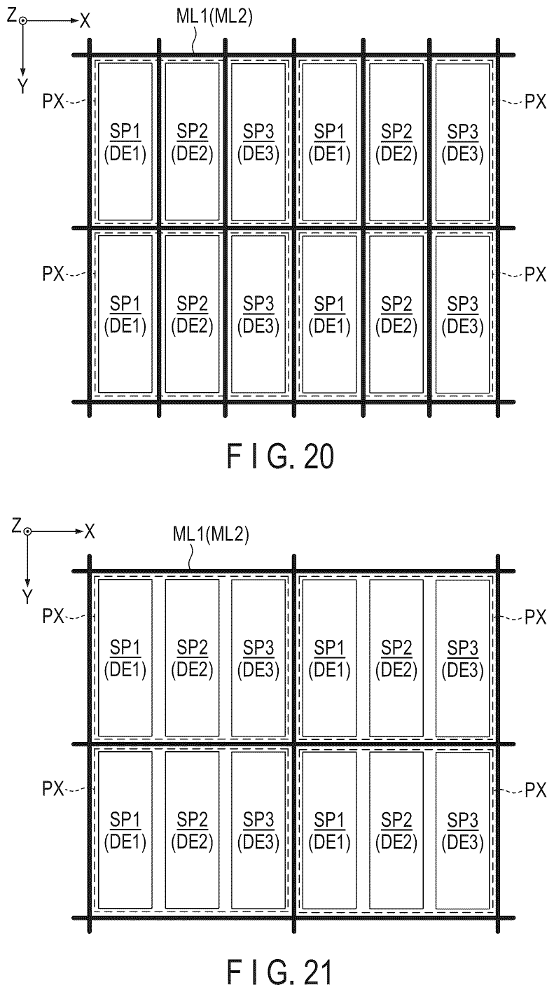

FIG. 20 is a schematic plan view of pixels PX and the first metal line ML1 according to a third modified example. In each pixel PX of the third modified example, subpixels SP1, SP2 and SP3 are arranged in the first direction X. For example, the widths of subpixels SP1, SP2 and SP3 in the second direction Y are equal to each other. The widths of subpixels SP1, SP2 and SP3 in the first direction X may be equal to each other or may be different from each other. When these pixels PX are arranged in matrix, a column in which a plurality of subpixels SP1 are successively provided in the second direction Y, a column in which a plurality of subpixels SP2 are successively provided in the second direction Y and a column in which a plurality of subpixels SP3 are successively provided in the second direction Y are formed in the display area DA.

In the third modified example, all of subpixels SP1, SP2 and SP3 are surrounded by the first metal line ML1. A similar configuration can be applied to the second metal line ML2.

FIG. 21 is a schematic plan view of pixels PX and the first metal line ML1 according to a fourth modified example. Each pixel PX of the fourth modified example includes subpixels SP1, SP2 and SP3 arranged in line with the same layout as FIG. 20.

In the fourth modified example, the first metal line ML1 is provided between adjacent pixels PX, and the first metal line ML1 is not provided between subpixels SP1, SP2 and SP3 included in each pixel PX. A similar configuration can be applied to the second metal line ML2.

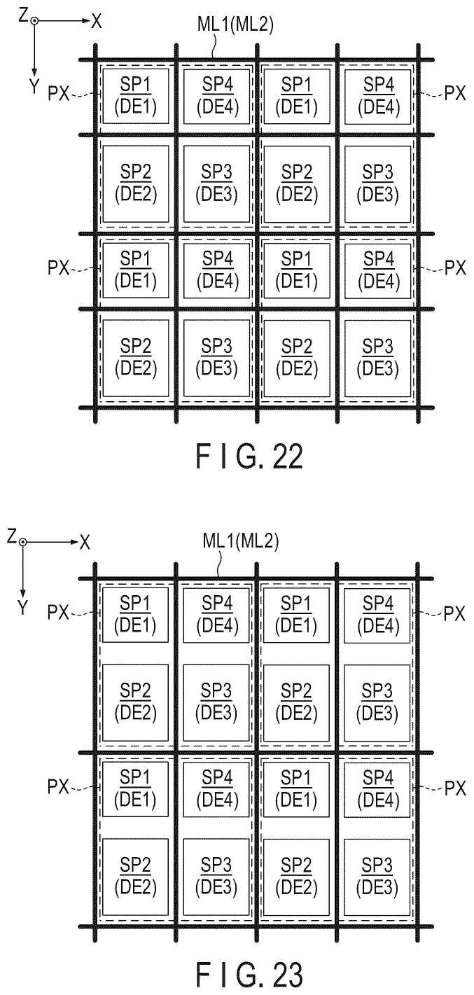

FIG. 22 is a schematic plan view of pixels PX and the first metal line ML1 according to a fifth modified example. Each pixel PX of the fifth modified example includes a white subpixel SP4 in addition to subpixels SP1, SP2 and SP3. Subpixel SP4 comprises a display element DE4 which emits white light. In each pixel PX, subpixel SP1 and subpixel SP4 are arranged in the first direction X, and subpixel SP2 and subpixel SP3 are arranged in the first direction X. Subpixel SP1 and subpixel SP2 are arranged in the second direction Y, and subpixel SP3 and subpixel SP4 are arranged in the second direction Y. The subpixel SP4 may emit light of any color other than white.

In the fifth modified example, all of subpixels SP1, SP2, SP3 and SP4 are surrounded by the first metal line ML1. A similar configuration can be applied to the second metal line ML2.

FIG. 23 is a schematic plan view of pixels PX and the first metal line ML1 according to a sixth modified example. Each pixel PX of the sixth modified example includes subpixels SP1, SP2, SP3 and SP4 arranged in line with the same layout as FIG. 22.

In the sixth modified example, the first metal line ML1 is provided between adjacent pixels PX. Further, the first metal line ML1 is provided between subpixels SP1 and SP4 included in each pixel PX and also between subpixels SP2 and SP3 included in each pixel PX. To the contrary, the first metal line ML1 is not provided between subpixels SP1 and SP2 included in each pixel PX or between subpixels SP3 and SP4 included in each pixel PX. A similar configuration can be applied to the second metal line ML2.

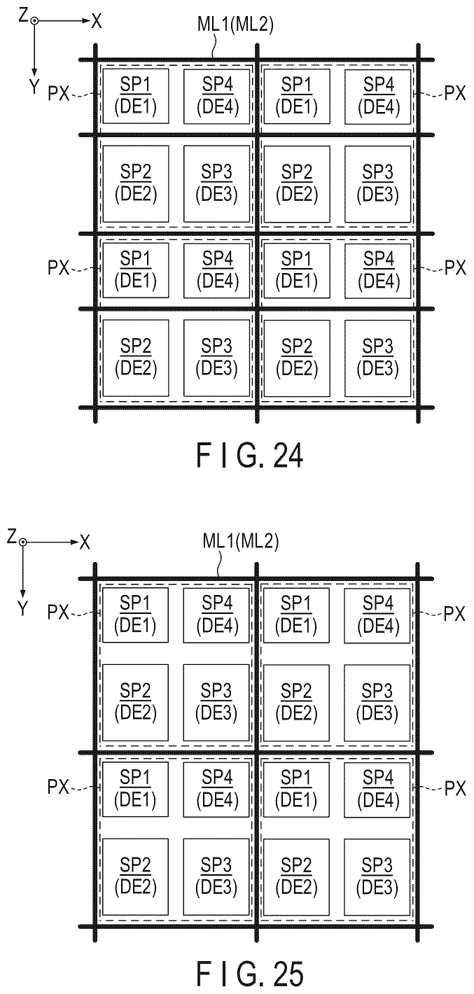

FIG. 24 is a schematic plan view of pixels PX and the first metal line ML1 according to a seventh modified example. Each pixel PX of the seventh modified example includes subpixels SP1, SP2, SP3 and SP4 arranged in line with the same layout as FIG. 22.

In the seventh modified example, the first metal line ML1 is provided between adjacent pixels PX. Further, the first metal line ML1 is provided between subpixels SP1 and SP2 included in each pixel PX and also between subpixels SP3 and SP4 included in each pixel PX. To the contrary, the first metal line ML1 is not provided between subpixels SP1 and SP4 included in each pixel PX or between subpixels SP2 and SP3 included in each pixel PX. A similar configuration can be applied to the second metal line ML2.

FIG. 25 is a schematic plan view of pixels PX and the first metal line ML1 according to an eighth modified example. Each pixel PX of the eighth modified example includes subpixels SP1, SP2, SP3 and SP4 arranged in line with the same layout as FIG. 22.

In the eighth modified example, the first metal line ML1 is provided between adjacent pixels PX, and the first metal line ML1 is not provided between subpixels SP1, SP2, SP3 and SP4 included in each pixel PX. A similar configuration can be applied to the second metal line ML2.

The first to eighth modified examples described above can be also applied to the embodiments described below. The configurations of the pixels PX, the first metal line ML1 and the second metal line ML2 can be appropriately modified in manners different from those of the first to eighth modified examples.

### Second Embodiment

A second embodiment is explained. The configurations which are not particularly referred to are the same as the first embodiment.

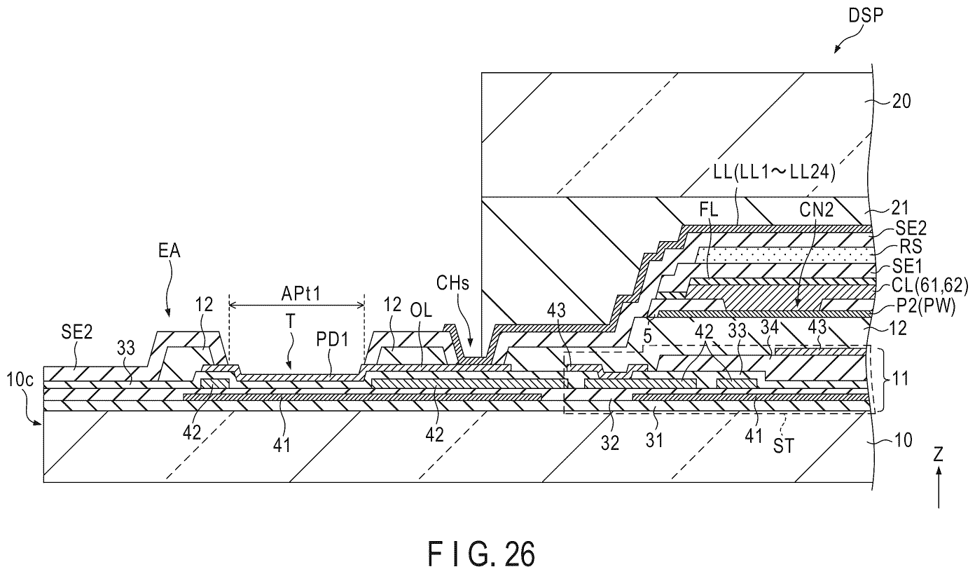

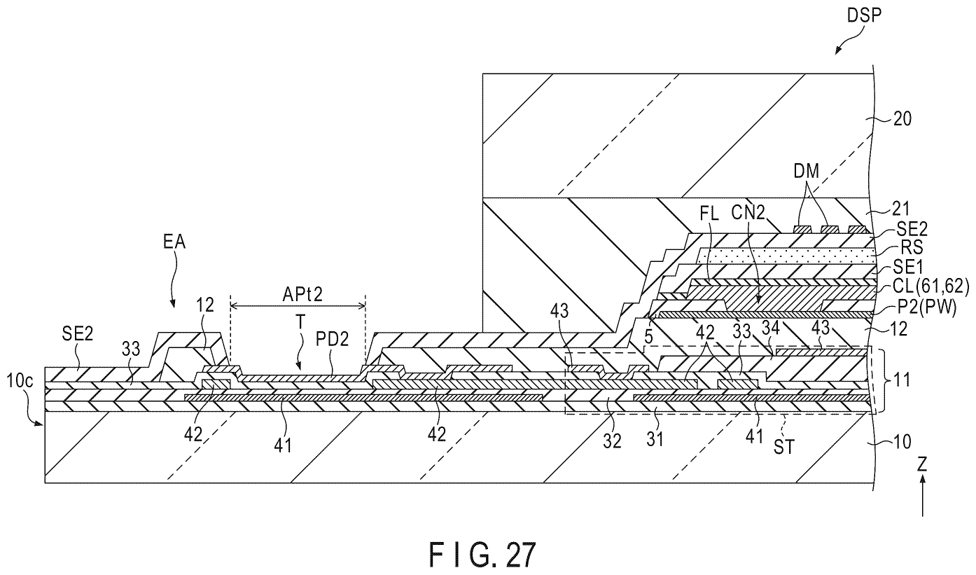

FIG. 26 and FIG. 27 are schematic cross-sectional views of the surrounding area SA of a display device DSP according to the second embodiment. FIG. 26 shows a section of the surrounding area SA including a first pad PD1 in a manner similar to that of FIG. 16. FIG. 27 shows a section of the surrounding area SA including a second pad PD2 in a manner similar to that of FIG. 17.

In the examples of FIG. 16 and FIG. 17, the organic insulating layer 12 is not formed near the terminal portion T. To the contrary, in the examples of FIG. 26 and FIG. 27, the organic insulating layer 12 is formed around the terminal portion T as well.

As shown in FIG. 26, the organic insulating layer 12 covers the rim of the first pad PD1 and an output line OL. The organic insulating layer 12 comprises an aperture which overlaps an aperture APt1. Further, a contact hole CHs penetrates the organic insulating layer 12 in addition to a second sealing layer SE2. A lead LL is connected to the output line OL through the contact hole CHs.

As shown in FIG. 27, the organic insulating layer 12 covers the rim of the second pad PD2. The organic insulating layer 12 comprises an aperture which overlaps an aperture APt2.

Even in the configuration of the present embodiment, effects similar to those of the first embodiment can be obtained. In the configuration of the present embodiment, a protrusion is formed by the organic insulating layer 12 around the first pad PD1 and the second pad PD2. By this configuration, the conductive adhesive which connects a flexible printed circuit FPC to the pads PD1 and PD2 is dammed up. Thus, this configuration can realize a good connection and conduction between the flexible printed circuit FPC and the pads PD1 and PD2.

### Third Embodiment

A third embodiment is explained. The configurations which are not particularly referred to are the same as each of the above embodiments.

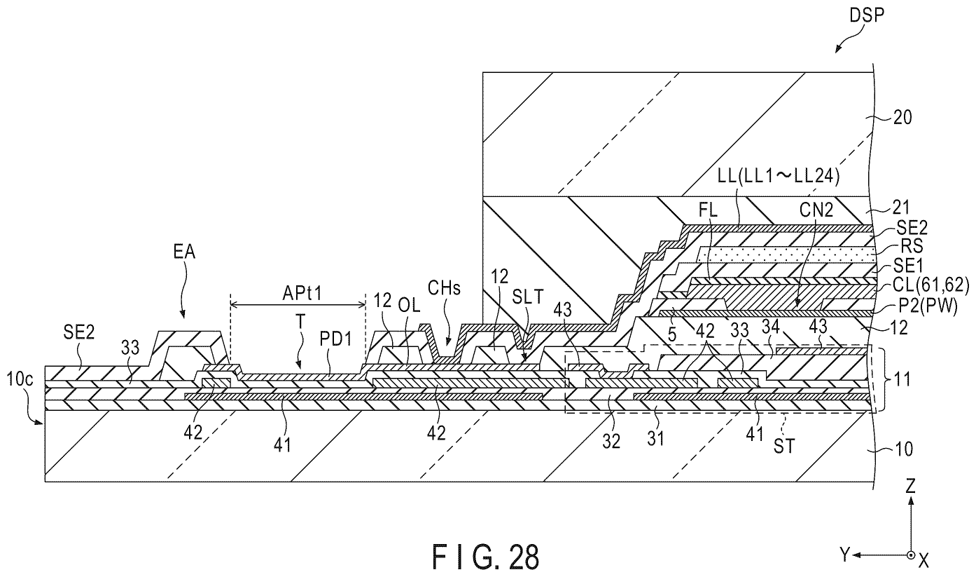

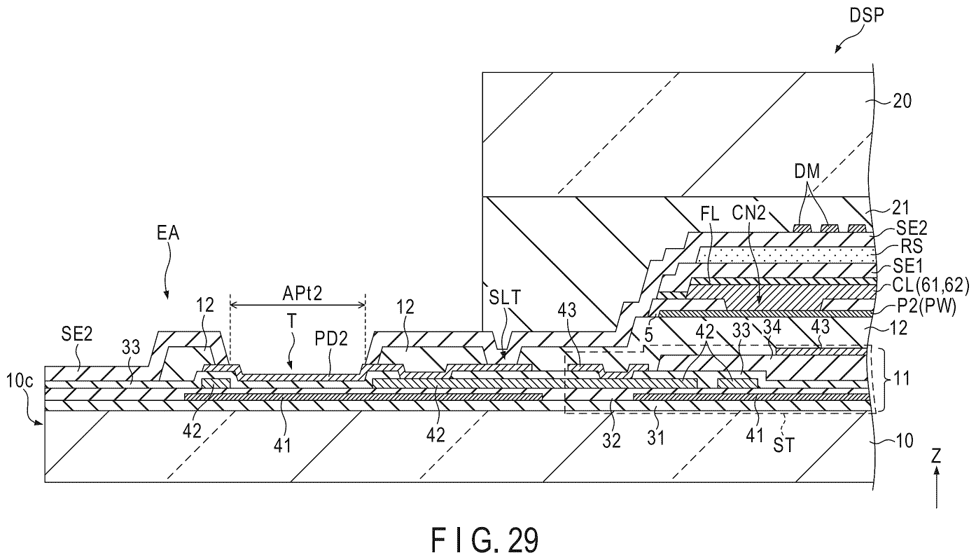

FIG. 28 and FIG. 29 are schematic cross-sectional views of the surrounding area SA of a display device DSP according to the third embodiment. FIG. 28 shows a section of the surrounding area SA including a first pad PD1 in a manner similar to that of FIG. 26. FIG. 29 shows a section of the surrounding area SA including a second pad PD2 in a manner similar to that of FIG. 27.

In the present embodiment, in a manner similar to that of the second embodiment, an organic insulating layer 12 is formed around a terminal portion T. Further, in the present embodiment, the organic insulating layer 12 comprises a slit SLT. The slit SLT penetrates the organic insulating layer 12.

For example, the slit SLT surrounds a display area DA. In other words, the slit SLT is located between the pads PD1 and PD2 and the display area DA as seen in plan view. More specifically, the slit SLT is located between a contact hole CHs and the display area DA as seen in plan view. In the section of FIG. 28, the slit SLT is located between the contact hole CHs and a conductive layer CL.

In the examples of FIG. 28 and FIG. 29, the slit SLT is covered with a second sealing layer SE2. A lead LL crosses the slit SLT. Further, a cover member 20 and an adhesive layer 21 are located above the slit SLT.

The provision of the slit SLT like the present embodiment can prevent moisture from entering the display device DSP through the organic insulating layer 12 from the vicinities of the pads PD1 and PD2. In particular, when the slit SLT is provided on the internal side relative to the contact hole CHs, the penetration of moisture from the vicinity of the contact hole CHs can be satisfactorily prevented.

### Fourth Embodiment

A fourth embodiment is explained. The configurations which are not particularly referred to are the same as each of the above embodiments.

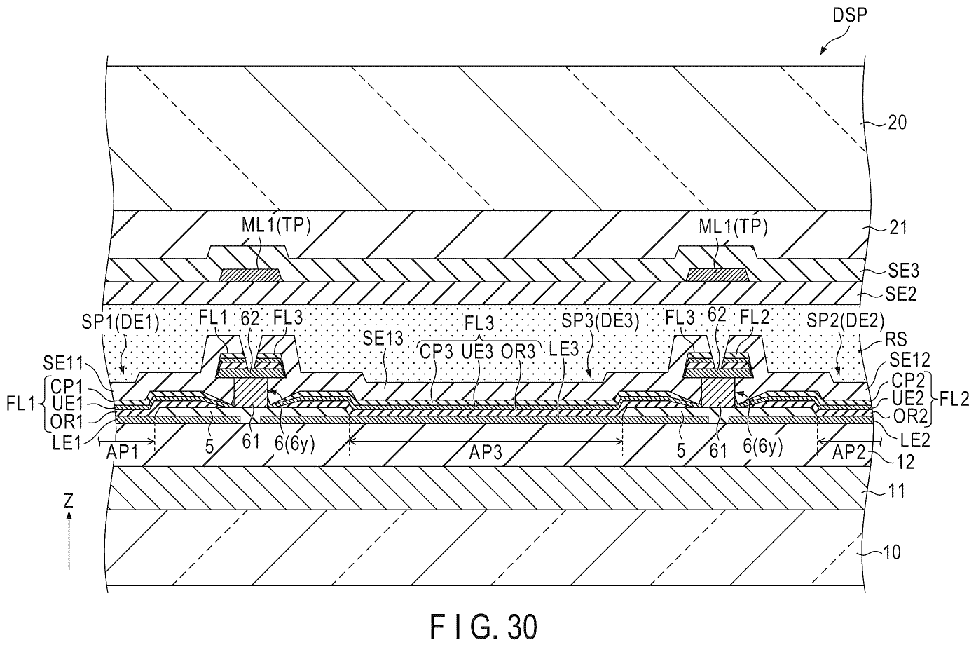

FIG. 30 is a schematic cross-sectional view of the display area DA of a display device DSP according to the fourth embodiment. In a manner similar to that of the example of FIG. 3, a first metal line ML1 is provided on a second sealing layer SE2. In the present embodiment, the first metal line ML1 is covered with a third sealing layer SE3. The third sealing layer SE3 is covered with an adhesive layer 21.

The third sealing layer SE3 is formed of an inorganic insulating material such as silicon nitride, silicon oxide or silicon oxynitride in a manner similar to that of the second sealing layer SE2.

The third sealing layer SE3 is provided in, for example, the entire display area DA and surrounding area SA. The third sealing layer SE3 comprises apertures having the same shapes as the apertures APt1 and APt2 of the second sealing layer SE2 in a terminal portion T. The third sealing layer SE3 covers a second metal line ML2, a lead LL and a dummy line DM in addition to the first metal line ML1.

When the third sealing layer SE3 is provided like the present embodiment, the first metal line ML1, the second metal line ML2, the lead LL, the dummy line DM and the like can be protected from moisture. The other effects are the same as the embodiments described above.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a plurality of display elements each including a lower electrode, an upper electrode which faces the lower electrode, and an organic layer which is provided between the lower electrode and the upper electrode and emits light based on a potential difference between the lower electrode and the upper electrode;
a partition which includes a conductive lower portion and an upper portion protruding from a side surface of the lower portion and surrounds each of the display elements; and
a touch panel electrode which detects an object contacting or approaching a display area including the display elements, wherein
the touch panel electrode includes a first metal line located above the partition and extending along the partition.

2. The display device of claim 1, further comprising a rib which comprises a plurality of pixel apertures overlapping the display elements, respectively, wherein
the partition is provided on the rib, and
a width of the first metal line is less than or equal to a width of the rib between the two adjacent pixel apertures.

3. The display device of claim 1, wherein
a width of the first metal line is less than or equal to a width of the upper portion.

4. The display device of claim 1, further comprising:
a plurality of first sealing layers which cover the display elements, respectively;
a resin layer which covers the first sealing layers; and
a second sealing layer which covers the resin layer, wherein
the first metal line is provided on the second sealing layer.

5. The display device of claim 4, further comprising:
a cover member which faces the second sealing layer; and
an adhesive layer which attaches the cover member to the second sealing layer, wherein
the first meal line is covered with the adhesive layer.

6. The display device of claim 4, further comprising a third sealing layer which covers the first metal line, wherein
each of the second sealing layer and the third sealing layer is formed of an inorganic insulating material.

7. The display device of claim 1, further comprising:
a terminal portion provided in a surrounding area around the display area;
a lead provided in the surrounding area and connected to the terminal portion; and
a relay line which connects the touch panel electrode to the lead.

8. The display device of claim 7, wherein
the relay line includes a second metal line located above the partition and extending along the partition.

9. The display device of claim 8, further comprising:
a plurality of first sealing layers which cover the display elements, respectively;
a resin layer which covers the first sealing layers; and
a second sealing layer which covers the resin layer, wherein
the first metal line and the second metal line are provided on the second sealing layer.

10. The display device of claim 8, wherein
the second metal line is located in the display area and surrounds at least one of the display elements as seen in plan view.

11. The display device of claim 7, further comprising a dummy line which is provided in the surrounding area and extends parallel to the lead.

12. The display device of claim 7, further comprising:
an organic insulating layer located below the lead; and
an output line located below the organic insulating layer, wherein
the terminal portion comprises a conductive pad located below the organic insulating layer and connected to the output line, and
the lead and the output line are connected to each other through a contact hole which penetrates the organic insulating layer.

13. The display device of claim 12, further comprising:
an adhesive layer which covers the first metal line and the lead; and
a cover member which faces the first metal line and the lead via the adhesive layer, wherein
the lead located in the contact hole is exposed from the adhesive layer.

14. The display device of claim 12, wherein
the organic insulating layer comprises a slit located between the pad and the display area.

15. The display device of claim 14, wherein
the lead crosses the slit.

16. The display device of claim 1, wherein
the first metal line surrounds at least one of the display elements as seen in plan view.
